(19) United States
(12) Patent Application Publication
(10) Pub. No.: US 2025/0089171 A1
(43) Pub. Date: Mar. 13, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventor: Seung Min LEE, Suwon-si (KR)

(73) Assignee: SAMSUNG ELECTRO-MECHANICS CO., LTD., Suwon-si (KR)

(21) Appl. No.: 18/672,545

(22) Filed: May 23, 2024

(30) Foreign Application Priority Data
Sep. 13, 2023 (KR) 10-2023-0121576

(51) Int. Cl. H05K 1/18; H01L 21/48; H01L 23/00; H01L 23/498; H05K 1/11; H05K 3/00; H05K 3/18

(52) U.S. Cl. CPC H05K 1/181; H01L 21/4853; H01L 23/49838; H01L 24/16; H05K 1/111; H05K 3/0023; H05K 3/181; H05K 3/188; H01L 2224/16113; H01L 2224/16238; H01L 2924/381; H05K 2201/0367; H05K 2201/09409; H05K 2201/09827; H05K 2201/1031; H05K 2201/10462; H05K 2203/0776

(57) ABSTRACT

The present disclosure relates to a printed circuit board including a first insulating layer, a pad disposed on an upper side of the first insulating layer, a protrusion disposed on the pad; and a metal post disposed on the pad and covering the protrusion, wherein the metal post has a tapered shape, such that a width of an upper surface of the metal post is smaller than a width of a lower surface of the metal post, and a method of manufacturing the printed circuit board.

### CROSS-REFERENCE TO RELATED APPLICATION(S)

This application claims benefit of priority to Korean Patent Application No. 10-2023-0121576 filed on Sep. 13, 2023 in the Korean Intellectual Property Office, the disclosure of which is incorporated herein by reference in its entirety.

### TECHNICAL FIELD

The present disclosure relates to a printed circuit board and a method of manufacturing the printed circuit board.

A multi-chip package including a memory chip such as a high bandwidth memory (HBM) or the like for processing exponentially increased data, a processor chip such as a central processing unit (CPU), a graphics processing unit (GPU), an application specific integrated circuit (ASIC), a field programmable gate array (FPGA), or the like, and the like, may be used due to recent developments in artificial intelligence (AI) technology or the like. In particular, the number of CPU and GPU cores in a server product has increased rapidly, and it is necessary to respond to a finer pitch of a chip metal post. In particular, when connecting a chip and a substrate, alignment of a connection member may be problematic, and defects may occur due to separation of a pad or a connection member due to occurrence of pressure, or defects of a short circuit between connection members may occur. Therefore, research is continuing to develop substrate and package structures that may reduce a pitch of a metal post in response to demand for higher density, improve connection reliability, and increase yield.

### SUMMARY

An object of the present disclosure is to provide a printed circuit board implementing a metal post with a fine pitch in the printed circuit board for mounting an electronic component, a semiconductor chip, or the like, and a method of manufacturing the printed circuit board.

An object of the present disclosure is to provide a printed circuit board implementing a protruding metal post, and a method of manufacturing the printed circuit board.

An object of the present disclosure is to provide a printed circuit board improving reliability, and a method of manufacturing the printed circuit board.

According to an aspect of the present disclosure, a printed circuit board includes a first insulating layer; a pad disposed on an upper side of the first insulating layer; a protrusion disposed on the pad; and a metal post disposed on the pad and covering the protrusion, in which the metal post has a tapered shape, such that a width of an upper surface of the metal post is smaller than a width of a lower surface of the metal post.

According to another aspect of the present disclosure, a method of manufacturing a printed circuit board includes forming a pad on a first insulating layer; forming a protrusion on the pad; and forming a metal post on the pad to cover the protrusion, in which the metal post has a tapered shape, such that a width of an upper surface of the metal post is smaller than a width of a lower surface of the metal post.

According to still another aspect of the present disclosure, a printed circuit board includes a first insulating layer; a pad disposed on an upper side of the first insulating layer; a protrusion disposed on and protruding upwardly from an upper surface of the pad, the protrusion having a width smaller than a width of the pad; and a metal post disposed on the pad and covering an upper surface and a side surface of the protrusion.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system.

FIG. 2 is a perspective view schematically illustrating an example of an electronic device.

FIG. 3 is a plan view schematically illustrating a printed circuit board according to an example.

FIG. 4 is a cross-sectional view schematically illustrating a printed circuit board according to an example.

FIG. 5 is a cross-sectional view schematically illustrating a printed circuit board according to another example.

FIGS. 6 to 13 are cross-sectional views schematically illustrating a method of manufacturing a printed circuit board according to an example.

### DETAILED DESCRIPTION

Hereinafter, the present disclosure will be described with reference to the accompanying drawings. The shapes and sizes of elements in the drawings may be exaggerated or reduced for clearer descriptions.

### Electronic Device

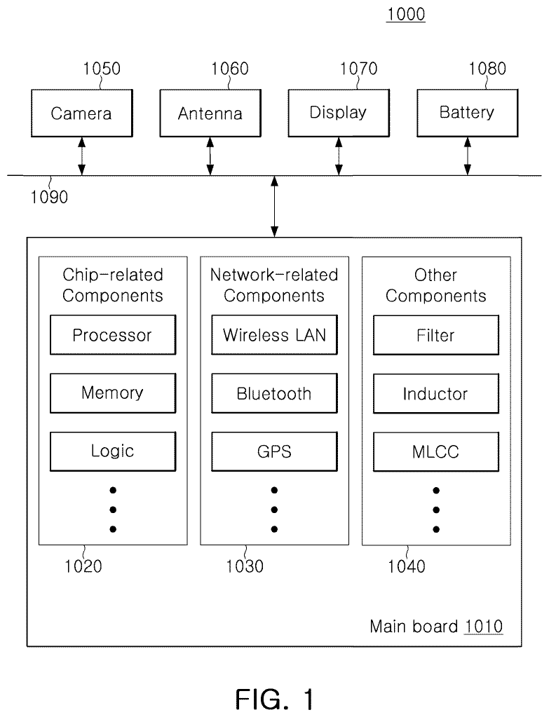

FIG. 1 is a block diagram schematically illustrating an example of an electronic device system.

Referring to the drawing, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like, but are not limited thereto, and may also include other types of chip related electronic components. In addition, the chip related components 1020 may also be combined with each other. The chip related components 1020 may be in the form of a package including the above-described chips or electronic components.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, or the like. In addition, other components 1040 may also be combined with each other, with the chip related components 1020 or the network related components 1030 described above.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like. However, these other electronic components are not limited thereto, and may also be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, other electronic components for various uses may also be included depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

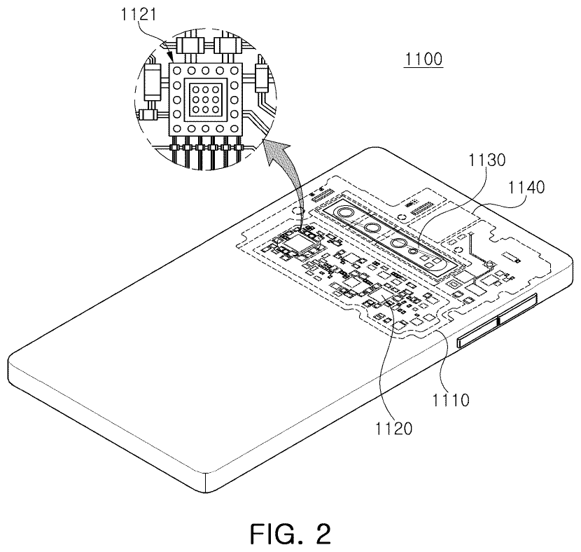

FIG. 2 is a perspective view schematically illustrating an example of an electronic device.

Referring to the drawing, an electronic device may be, for example, a smartphone 1100. A motherboard 1110 may be accommodated inside the smartphone 1100, and various components 1120 may be physically or electrically connected to the motherboard 1110. In addition, other components that may or may not be physically or electrically connected to the motherboard 1110, such as a camera module 1130 and/or a speaker 1140, may be accommodated therein. Some of the electronic components 1120 may be the above-described chip related components, for example, a component package 1121, but are not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. The electronic device is not necessarily limited to the smartphone 1100, and may also be other electronic devices as described above.

### Printed Circuit Board

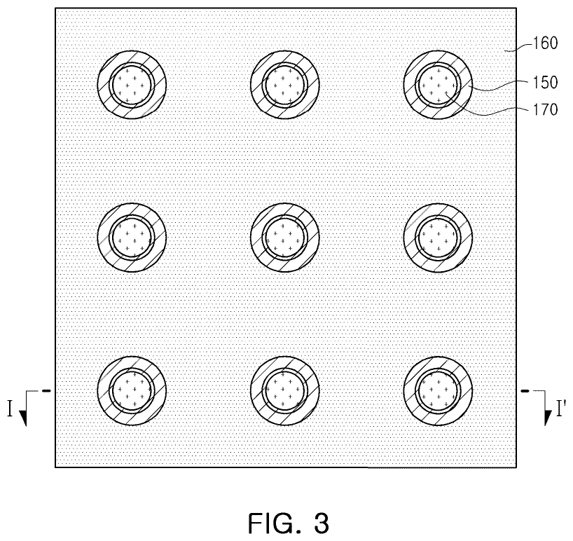

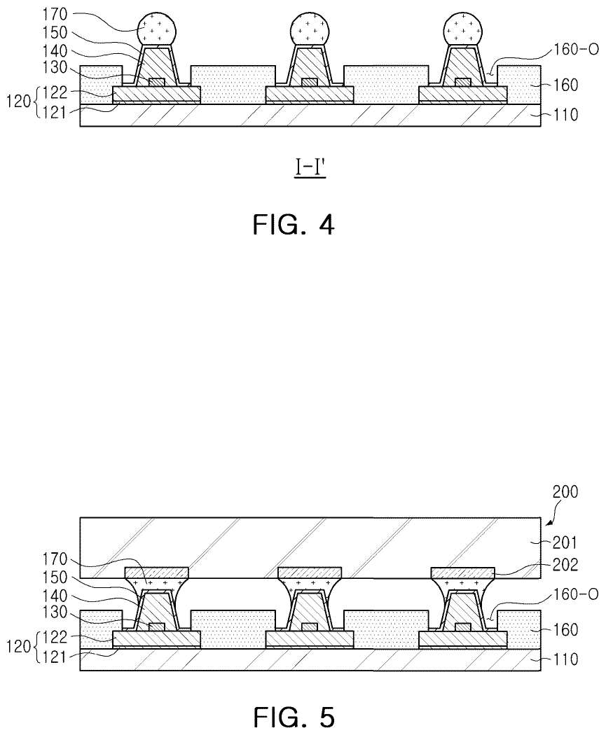

FIG. 3 is a plan view schematically illustrating a printed circuit board according to an example, and FIG. 4 is a cross-sectional view schematically illustrating a printed circuit board according to an example. Specifically, FIG. 3 may be a top-view plan view of a printed circuit board according to an example, as seen from the top, and FIG. 4 may be a cross-sectional view of the printed circuit board of FIG. 3, taken along line I-I′.

Referring to FIG. 3, a printed circuit board according to an example may have a region for mounting a semiconductor chip, etc. A printed circuit board according to an example may have an upper surface covered with a solder resist layer 160, and a pad 120 and a metal post 140 may be exposed through an opening in the solder resist layer 160. A surface treatment layer 150 may be disposed on exposed surfaces of the pad 120 and the metal post 140. A connection member 170 may be disposed on the metal post 140. A printed circuit board according to an example may have the metal post 140 protruding beyond an insulating layer, and it is advantageous when mounting a semiconductor chip having a fine pitch, etc. by the protruding metal post 140. A printed circuit board according to an example may be described in more detail through a cross-sectional view of FIG. 4.

Referring to FIG. 4, a printed circuit board according to an example may include a first insulating layer 110, a pad 120 disposed on an upper side of the first insulating layer 110, a protrusion 130 disposed on the pad 120, and a metal post 140 disposed on the pad 120 and covering the protrusion 130. The protrusion 130 may be disposed to protrude upwardly from an upper surface of the pad 120, and may have a width smaller than a width of the pad 120.

The first insulating layer 110 may include an insulating material. The insulating material may include a thermosetting resin such as an epoxy resin, a thermoplastic resin such as polyimide, or a material containing these resins along with an inorganic filler, an organic filler, and/or a glass fiber, a glass cloth, and/or a glass fabric. The insulating material may be a photosensitive material and/or a non-photosensitive material. For example, the insulating material of the first insulating layer 110 may be an insulating material of an Ajinomoto build-up film (ABF), but the present disclosure is not limited thereto, and may include a prepreg (PPG), a resin coated copper (RCC), a photoimageable dielectric (PID), an FR-4, bismaleimide triazine (BT), etc. However, it may not be limited thereto, and as necessary, other materials with excellent rigidity may be used.

The pad 120 may include a metal material. As the metal material, copper (Cu), aluminum (Al), silver (Ag), tin (Sn), gold (Au), lead (Pb), titanium (Ti), or alloys thereof may be used. The metal material may preferably include copper (Cu), but the present disclosure is not limited thereto. The pad 120 may be a region for mounting an electronic component, a chip, etc., and may be connected to a circuit pattern to perform signal connection with other pads. The pad 120 may perform various functions depending on a design thereof. For example, the pad 120 may include a ground pad, a power pad, a signal pad, etc. In this case, the signal pad may include a pad for electrical connection of various signals other than ground, power, etc., for example, a data signal, etc. When the pad 120 requires high density and a fine pitch for mounting a semiconductor chip, etc., a gap between pads 120 may be narrowed, and for mounting electronic components, a gap between pads 120 may be widened.

The pad 120 may be formed as a plurality of pads. The plurality of pads 120 may be formed simultaneously in an operation of forming the pad 120, but the present disclosure is not limited thereto, and may be formed sequentially or stepwise, as needed. Additionally, the pad 120 may electrically transmit and receive a signal with other pads 120 and/or circuits, and may also perform a function thereof with being electrically shorted to other pads 120.

The pad 120 may be formed using any one of a semi-additive process (SAP), a modified semi-additive process (MSAP), a tenting (TT) process, or a subtractive process, but the present disclosure is not limited thereto. The pad 120 may be composed of a first metal layer 121 disposed on the first insulating layer 110, and a second metal layer 122 disposed on the first metal layer 121.

The first metal layer 121 and the second metal layer 122 may include a metal material, and may be selected from the group of metal materials of the pad 120 described above. The first metal layer 121 and the second metal layer 122 may include the same metal, and preferably, the first metal layer 121 and the second metal layer 122 may each include copper (Cu), but the present disclosure is not limited thereto, and the first metal layer 121 and the second metal layer 122 may include different metals, as needed.

The first metal layer 121 may be disposed on the first insulating layer 110, and may function as a seed for forming the second metal layer 122, the protrusion 130, and the metal post 140. The first metal layer 121 may include an electroless plating layer (or chemical copper) formed by electroless plating, but the present disclosure is not limited thereto, may include a sputtering layer formed by sputtering, instead of electroless plating, or may include the electroless plating layer and the sputtering layer. However, the present disclosure is not limited thereto, and as necessary, any metal that may function as a seed for electroplating, such as a copper foil, may be used without limitation.

The second metal layer 122 may be disposed on the first metal layer 121, and may be formed using the first metal layer 121, as a seed. The second metal layer 122 may include an electroplating layer (or electroplated copper) formed by electroplating. However, the present disclosure is not limited thereto, and the second metal layer 122 may be formed by sintering a paste containing a metal material. A method of forming the second metal layer 122 is not limited thereto, and may further include a configuration or a method that may be used by those skilled in the art.

In FIG. 4, the pad 120 is illustrated as being disposed on the first insulating layer 110, but the pad 120 is not necessarily limited thereto. The placement of the pad 120 on the upper side of the first insulating layer 110 may not only include a configuration in which the pad 120 is disposed on an upper surface of the first insulating layer 110, as illustrated in FIG. 4, but also include a configuration in which the pad 120 is disposed on the upper side of the first insulating layer 110, and embedded in the first insulating layer 110. For example, the pad 120 may have a structure buried in the upper side of the first insulating layer 110, and in this case, a printed circuit board according to an example may have a so-called coreless substrate structure. When the pad 120 is buried in the upper side of the first insulating layer 110, the first metal layer 121 of the pad 120 may be disposed such that the first insulating layer 110 faces in an upward direction, etc. Arrangement of the first metal layer and the second metal layer 122 may be changed, and in some cases, the pad 120 may not include the first metal layer 121. For example, in the coreless substrate structure, arrangement of seeds may be different from that of FIG. 4, and in some cases, the seeds may be removed. In the coreless substrate structure, the protrusion 130 may be disposed on the pad 120 embedded in the upper side of the first insulating layer 110, after detaching a carrier substrate. The coreless substrate structure is not limited to the above-described content, and may include a configuration of a substrate that may be used by those skilled in the art.

The protrusion 130 may be disposed on the second metal layer 122 of the pad 120. A width of the protrusion 130 may be smaller than a width of the pad 120, and the protrusion 130 may be disposed in a central portion of the pad 120, but the present disclosure is not limited thereto. The protrusion 130 may include a metal material, and, as the metal material, copper (Cu), aluminum (Al), silver (Ag), tin (Sn), gold (Au), lead (Pb), titanium (Ti), or alloys thereof may be used. The metal material may preferably include copper (Cu), and may include the same metal material as the second metal layer 122 of the pad 120, but the present disclosure is not necessarily limited thereto. The protrusion 130 may be formed by electroplating using the first metal layer 121 of the pad 120 as a seed, but the present disclosure is not necessarily limited thereto, and may further include a configuration or a method that may be used by those skilled in the art. The protrusion 130 is not limited thereto, and may include an insulating material. The insulating material may be a photosensitive insulating material or a non-photosensitive insulating material. The protrusion 130 may be formed by patterning a photosensitive insulating material, or may be formed by disposing and curing an insulating material on the pad 120. Alternatively, the protrusion 130 may include an oxide. The protrusion 130 does not necessarily have to correspond to any one of the above-mentioned materials, and may be sufficient if have a structure disposed on the pad 120 and protruding onto a portion of the pad 120.

Since the protrusion 130 may be disposed on the pad 120 and formed in a separate operation from the pad 120, the protrusion 130 may be distinguished from the pad 120. For example, even when the protrusion 130 and the second metal layer 122 of the pad 120 include the same metal material, a boundary therebetween may be distinguished, and may be confirmed by observing a cross-section of the printed circuit board with a scanning microscope. Alternatively, the boundary between the second metal layer 122 of the pad 120 and the protrusion 130 may be confirmed by performing a certain process on a cross-section of the printed circuit board and observing grain boundaries of the metal material.

The protrusion 130 may be disposed on the pad 120 to control a shape of the metal post 140. In forming an opening in a dry film to form the metal post 140, the protrusion 130 may be disposed on a portion of the pad 120, such that a shape tapered in an upward direction may be obtained in exposing and developing the dry film. For example, in the exposing and developing the dry film, an opening having a tapered shape, such that a width of an upper side is smaller than a width of a lower side may be formed by the protrusion 130.

A thickness of the protrusion 130 may be smaller than a thickness of the pad 120. The protrusion 130 may be disposed on the pad 120 to serve as an intermediate for forming the metal post 140, and may have the thickness, smaller than the thickness of the pad 120. The thickness of the protrusion 130 and the thickness of the pad 120 may be measured by photographing a cross-section of the printed circuit board in a stacking direction using a scanning microscope or the like. A thickness of a component may be interpreted as a distance across the component vertically, but may include a measurement error or an error in a manufacturing process. For example, the thickness of the pad 120 may be an average value of vertical distances between lower and upper surfaces of the pad 120 measured at five arbitrary points with respect to a single pad 120. The thickness of the protrusion 130 may also be measured and compared in the same manner.

The metal post 140 may be disposed on the pad 120 to cover the protrusion 130. The metal post 140 may have a tapered shape, such that a width of an upper surface is smaller than a width of a lower surface.

The metal post 140 may include a metal material. As the metal material, copper (Cu), aluminum (Al), silver (Ag), tin (Sn), gold (Au), lead (Pb), titanium (Ti), or alloys thereof may be used. The metal material may preferably include copper (Cu), but the present disclosure is not limited thereto. The metal post 140 may be a region for mounting an electronic component, a chip, etc., and may be configured to protrude to facilitate smooth connection when the electronic component, the chip, etc. are mounted on the pad 120. The metal post 140 may perform various functions depending on a design of the pad 120. When the pad 120 requires a high density and a fine pitch for mounting a semiconductor chip, etc., not only may a gap between pads 120 be narrowed, but also a gap between metal posts 140 may be narrowed. The metal post 140 may be formed of a plurality of metal posts 140. The plurality of metal posts 140 may be formed simultaneously in forming the metal post 140, but the present disclosure is not limited thereto, and may be formed sequentially or stepwise, as needed. Additionally, the metal post 140 may electrically transmit and receive a signal to and from the pad 120.

The metal post 140 may be formed using any one of a semi-additive process (SAP), a modified semi-additive process (MSAP), a tenting (TT) process, or a subtractive process, but the present disclosure is not limited thereto. The metal post 140 may be formed by electroplating using the first metal layer 121 of the pad 120 as a seed, but the present disclosure is not necessarily limited thereto, and may be formed using any existing method by anyone skilled in the art.

Since the metal post 140 may be formed to fill an opening of a dry film, a shape of the metal post 140 may be determined by a shape of the opening of the dry film. As described above, as the protrusion 130 is disposed on the pad 120, the opening of the dry film may have a tapered shape, such that a width of an upper surface is smaller than a width of a lower surface, and accordingly, the metal post 140 may have the tapered shape, such that the width of the upper surface is smaller than the width of the lower surface. A width of the metal post 140 may be measured by photographing a cross-section of the printed circuit board in a stacking direction using a scanning microscope or the like. A width of a component may be interpreted as a distance across the component horizontally, but may include a measurement error or an error in a manufacturing process. In FIG. 4, the shape of the metal post 140 is illustrated to change linearly with a constant rate of change, but this is only illustrative, and an inclined surface of a side surface of the metal post 140 may be curved, such that a side portion is curved.

The width of the metal post 140 may be smaller than the width of the pad 120. The width of the pad 120 may also be measured by photographing a cross-section of the printed circuit board in a stacking direction using a scanning microscope or the like. For example, the width of the pad 120 may be an average value of horizontal distances between side surfaces of the pad 120 measured at five arbitrary points with respect to a single pad 120. When the pad 120 has a circular shape, the width of the pad 120 may mean a diameter of the pad 120. When the pad 120 has a polygonal shape, the width of the pad 120 may be measured as a diagonal of a polygon or a distance between two opposite side surfaces of the polygon. When the pad 120 has an elliptical shape, the width of the pad 120 may be defined as a short axis of an ellipse. As described above, since the width of the metal post 140 may be different from the width on the upper surface and the width on the lower surface, the width of the metal post 140 for comparison with the width of the pad 120 may be a width measured from a surface on which the pad 120 and the metal post 140 are in contact. In this case, the width of the metal post 140 may be a width measured including the protrusion 130 located in a central portion of the metal post 140. For example, the width of the metal post 140 may mean a distance of an outer surface of the metal post 140 including the protrusion 130.

As the metal post 140 may be disposed on the pad 120, even when a semiconductor chip having a fine pitch is mounted, a possibility that the connection member 170 disposed between the semiconductor chip and the metal post 140 is circuit-shorted may be reduced, and defects that the semiconductor chip is detached may also be reduced. In addition, when the metal post 140 is disposed on the pad 120, a better degree of adhesion may be secured, as compared to a structure in which the connection member 170 is directly disposed on the pad 120, and through this, reliability of the printed circuit board may be improved.

A printed circuit board according to an example may further include a solder resist layer 160 on the first insulating layer 110. The solder resist layer 160 may be disposed on the first insulating layer 110, and may be disposed on an outermost side of the printed circuit board to protect the printed circuit board from the outside. The solder resist layer 160 may use a known solder resist, and the solder resist layer 160 may include a thermosetting resin and an inorganic filler dispersed in the thermosetting resin, but may not include a glass fiber. An insulating resin may be a photosensitive insulating resin, and the filler may be an inorganic filler and/or an organic filler, but the present disclosure is not limited thereto, and other polymer materials may be used, as needed. When the photosensitive insulating resin is used as the solder resist layer 160, it may be advantageous to form a fine opening, and in this case, it may be more advantageous for printed circuit boards having a fine pitch. Additionally, the solder resist layer 160 may include a liquid material. The inclusion of the liquid material in the solder resist layer 160 may mean that forming the solder resist layer 160 may include, after applying the liquid material, exposing, developing, and curing the liquid material. Since a printed circuit board according to an example includes the protruding metal post 140, when the solder resist layer 160 includes the liquid material, the solder resist layer 160 may be disposed conformally along a boundary of the protruding metal post 140. When the solder resist layer 160 is provided as a film, a heat press process may be performed. Therefore, there may be a risk that some deformation may occur in the protruding metal post 140 during the heat press process. However, the solder resist layer 160 is not necessarily limited thereto, and when defects do not occur in the protruding metal post 140 by controlling a thickness, a degree of hardness, and other characteristics in forming the solder resist layer 160, a film-shaped material may be used.

The solder resist layer 160 may have an opening 160-O, and the metal post 140 may protrude through the opening 160-O. The fact that the metal post 140 protrudes through the opening 160-O of the solder resist layer 160 may mean that an upper surface of the metal post 140 may be located higher than an upper surface of the solder resist layer 160, and, additionally, may mean that at least a portion of a side surface of the metal post 140 is not covered by the solder resist layer 160, but the present disclosure is not limited thereto.

The opening 160-O of the solder resist layer 160 may expose at least a portion of the pad 120. The fact that at least a portion of the pad 120 is exposed through the opening 160-O of the solder resist layer 160 may mean that the solder resist layer 160 does not entirely cover the pad 120, but at least a portion of the pad 120 is not covered by the solder resist layer 160. The opening 160-O of the solder resist layer 160 may expose at least a portion of an upper surface of the pad. In this case, since other components may be further disposed on the pad 120, the fact that the opening 160-O of the solder resist layer 160 exposes at least a portion of the pad 120 may not mean that at least a portion of the pad 120 should be exposed to the outside of the printed circuit board, and the exposure may mean a relationship between the solder resist layer 160 and the pad 120. The solder resist layer 160 may cover at least a portion of the upper surface of the pad 120. A width of the opening 160-O of the solder resist layer 160 may be smaller than a width of the pad 120. In this case, the solder resist layer 160 may cover at least a portion of the upper surface of the pad 120.

In FIG. 4, although the opening 160-O of the solder resist layer 160 is illustrated to expose at least a portion of the upper surface of the pad 120 and a side surface of the metal post 140, but the present disclosure is not limited thereto, and the opening 160-O of the solder resist layer 160 may entirely cover the upper surface of the pad 120, and may also cover at least a portion of the side surface of the metal post 140. As a non-limiting example, the opening 160-O of the solder resist layer 160 may expose a side surface of the pad 120. The metal post 140 and/or the pad 120 exposed through the opening 160-O may be connected to other components, such as a semiconductor chip or the like, through the connection member 170.

A printed circuit board according to an example may further include a surface treatment layer 150 disposed on the metal post 140 and/or the pad 120. The surface treatment layer 150 may include any one metal of nickel (Ni), palladium (Pd), or gold (Au), and a plurality of metal layers may be implemented. For example, the surface treatment layer 150 may be at least a portion of an electroless nickel electroless palladium immersion gold (ENEPIG) structure, or may be at least a portion of an electroless nickel immersion gold (ENIG) structure. The surface treatment layer 150 is not limited thereto, and may include an organic solder passivation (OSP) structure containing an organic material. The surface treatment layer 150 may improve adhesion and signal transmission between the metal post 140 and pad 120 and the connection member 170. In FIG. 4, the surface treatment layer 150 is illustrated as a single layer, but the present disclosure is not limited thereto, and the surface treatment layer 150 may be implemented as a plurality of metal layers, as described above.

The surface treatment layer 150 may cover at least a portion of the metal post 140, and may also cover at least a portion of the pad 120. The surface treatment layer 150 may cover a portion of the metal post 140 and pad 120 exposed by the opening 160-O of the solder resist layer 160. In this case, since the surface treatment layer 150 may be formed after forming the solder resist layer 160 and the opening 160-O, the surface treatment layer 150 may be formed integrally along boundaries of the metal post 140 and the pad 120 exposed by the opening 160-O.

A printed circuit board according to an example may further include a connection member 170 disposed on the metal post 140. The connection member 170 may include a conductive material, and may include, for example, a solder composed of tin (Sn)-silver (Ag), or copper, but a material of the connection member 170 is not limited thereto, and may further include a material that may be used by those skilled in the art. The connection member 170 may be disposed on the metal post 140 in the form of a ball, but the present disclosure is not limited thereto.

In a printed circuit board according to an example, the connection member 170 may be disposed before other components, such as a semiconductor chip or the like, are mounted on the printed circuit board. For example, the connection member 170 may maintain a position thereof disposed on the metal post 140 before other components, such as a semiconductor chip or the like, are mounted, and may form a printed circuit board on which a so-called micro-ball is disposed. Since a printed circuit board according to an example has a shape in which the metal post 140 is tapered in an upward direction, it is possible to implement a finer connection member 170, and through this, a semiconductor chip having a fine pitch may be mounted. As the connection member 170 is disposed all at once on the metal post 140 of the printed circuit board, it may be advantageous to align the semiconductor chip and the connection member 170, unlike forming a connection member 170 in an operation of mounting a semiconductor chip.

A printed circuit board according to an example is not limited to the configuration illustrated in FIG. 4, and FIG. 4 illustrates only a portion of the printed circuit board, and other components may be further included. For example, other components, such as an insulating layer, a circuit, an interlayer via, or the like may be further included on a lower side of the first insulating layer 110. For example, a component that may be used by anyone with ordinary knowledge in the relevant technical field may be further included.

FIG. 5 is a cross-sectional view schematically illustrating a printed circuit board according to another example.

Referring to FIG. 5, a printed circuit board according to another example may further include a semiconductor chip 200 disposed on a connection member 170.

The semiconductor chip 200 may be an integrated circuit (IC) in which hundreds to millions of chips are integrated into a single chip. These may be processor chips such as a central processor (e.g., CPU), a graphics processor (e.g., GPU), a field programmable gate array (FPGA), a digital signal processor, a cryptographic processor, a microprocessor, a microcontroller, or the like, specifically an application processor (AP), but the present disclosure is not limited thereto, and may be logic chips such as an analog-digital converter, an application-specific integrated circuit (ASIC) memory controller (MC) chip, or memory chips such as a dynamic random access memory (DRAM) chip, a static random access memory (SRAM) chip, a flash memory chip, a phase-change random access memory (PRAM) chip, a magnetic random access memory (MRAM) chip, a resistive random access memory (RRAM) chip, an electrically erasable and programmable read-only memory (EEPROM) chip, a high bandwidth memory (HBM) chip, or the like, and these may be disposed in combination with each other.

The semiconductor chip 200 may be composed of a body 201 and a connection pad 202, and a surface on which the connection pad 202 for connection to a metal post 140 is disposed may be an active surface, a surface opposite thereto may be an inactive surface, but the present disclosure is not limited thereto, and double-sided connection is possible, and in some cases, the semiconductor chip 200 may have a three-dimensional structure. The semiconductor chip 200 may be formed based on an active wafer, and in this case, silicon (Si), germanium (Ge), gallium arsenide (GaAs), etc. may be used as a base material forming the body 201. Various circuits may be formed in the body 201 of the semiconductor chip 200, and at least a portion of these circuits may be connected to the connection pad 202. In FIG. 5, the connection pad 202 is illustrated as being embedded in the body 201 of the semiconductor chip 200, but is only illustrative, and the connection pad 202 may be separated from the body 201 of the semiconductor chip 200. A specific structure of the semiconductor chip 200 is not limited to those illustrated in the drawing, such as the connection pad 202 may have a structure protruding from the body 201 of the semiconductor chip 200, a structure in which the connection pad 202 is buried by surface treatment or molding, or the like.

The connection pad 202 of the semiconductor chip 200 may be connected to the metal post 140 through the connection member 170, and may be connected to the pad 120 through the metal post 140, such that the semiconductor chip 200 may be electrically connected to other components of the printed circuit board.

In this case, the connection member 170 connecting the semiconductor chip 200 and the metal post 140 may have a width on the connection pad 202 of the semiconductor chip 200, greater than a width on the metal post 140. This may be a phenomenon caused by a surface tension of the connection member 170, and may occur when a width of an upper surface of the metal post 140 is smaller than a width of the connection pad 202 of the semiconductor chip 200. For example, the metal post 140 has particularly a protruding structure having a shape tapered in an upward direction, and may thus respond to the fine pitch of the semiconductor chip 200. As a result, the connection member 170 may have a width on the semiconductor chip 200, greater than a width on the metal post 140. In this case, for the semiconductor chip 200 to be connected to the connection member 170, an operation of heating at least a portion of the connection member 170 may be included, such that a portion of the connection member 170 having a low melting point may be disposed to cover a portion of the metal post 140. It is not necessarily limited thereto, and a width on the metal post 140 may be formed to be wider.

In this case, the connection member 170 may have a shape like a so-called hourglass in which a width on an upper side, greater than a width on a lower side.

Among configurations other than arrangement of the semiconductor chip 200 and a shape of the connection member 170, the same configuration as that of a printed circuit board according to an example may be applied to the printed circuit board according to another example. Therefore, overlapping description regarding this will be omitted.

### Method of Manufacturing Printed Circuit Board

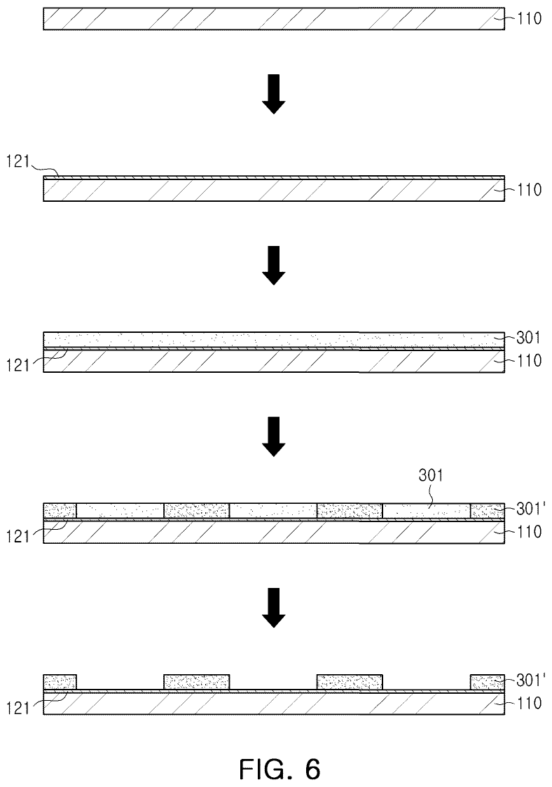

FIGS. 6 to 13 are cross-sectional views schematically illustrating a method of manufacturing a printed circuit board according to an example.

A method of manufacturing a printed circuit board according to an example may include forming a pad 120 on a first insulating layer 110; forming a protrusion 130 on the pad 120; and forming a metal post 140 on the pad 120 to cover the protrusion 130. In this case, the metal post 140 may have a tapered shape, such that a width of an upper surface is smaller than a width of a lower surface. The forming a metal post 140 may include forming a dry film 303 on the first insulating layer 110, exposing and developing at least a portion of the dry film 303 to expose at least a portion of the pad 120 and at least a portion of the protrusion 130, and forming the metal post 140 on the pad 120. In this case, the developing at least a portion of the dry film 303 may include injecting a developer containing a liquid material, to form an opening having a tapered shape, such that a width of an upper surface is smaller than a width of a lower surface.

Referring to FIG. 6, a method of manufacturing a printed circuit board according to an example may include forming a first metal layer 121 on a first insulating layer 110. The first metal layer 121 may be formed by performing electroless plating, and in some cases, may be formed by sputtering, etc. As a non-limiting example, the first insulating layer 110 to which the first metal layer 121 is attached in the form of copper foil may be used.

Thereafter, a first dry film 301 may be formed. The first dry film 301 may include a photosensitive insulating material. For example, the first dry film 301 may be a normal photosensitive resist film, and may use a dry film resist (DFR), but is not particularly limited thereto. The first dry film 301 may be formed on an upper surface of the insulating layer by laminating, but is not particularly limited thereto. The first dry film 301 may be formed by coating and curing the photosensitive insulating material on the upper surface of the first insulating layer 110, but is not particularly limited thereto, and may be formed on at least a portion of the upper surface of the first insulating layer 110.

There may be no limitations as long as the method may form the first dry film 301. The first dry film 301 may function as a plating mask during electrolytic plating. The first dry film 301 may be a positive type or a negative type. When a positive type photosensitive insulating material is included, photopolymer bonding in an exposed portion may be broken, and a portion in which the photopolymer bonding is broken may be removed in a subsequent development process. When a negative type photosensitive insulating material is included, a photopolymerization reaction may occur in an exposed portion, to change from a single structure to a three-dimensional network structure having a chain structure, and a portion that does not receive light may be removed in a subsequent development process.

Thereafter, the first dry film 301 may be exposed to deform at least a portion of the first dry film 301. In this case, an exposed region may be different, depending on a type of the first dry film 301. In FIG. 6, the exposed portion of the first dry film 301 is illustrated to be modified, and this is only illustrative. A mask or the like may be used to partially deform the first dry film 301.

Thereafter, the first dry film 301 may be developed to remove at least a portion of the first dry film 301. A region from which the at least a portion of the first dry film 301 is removed may be a location in which the pad 120 is later formed. Operations of exposing and developing the first dry film 301 may be performed using any method available to those skilled in the art.

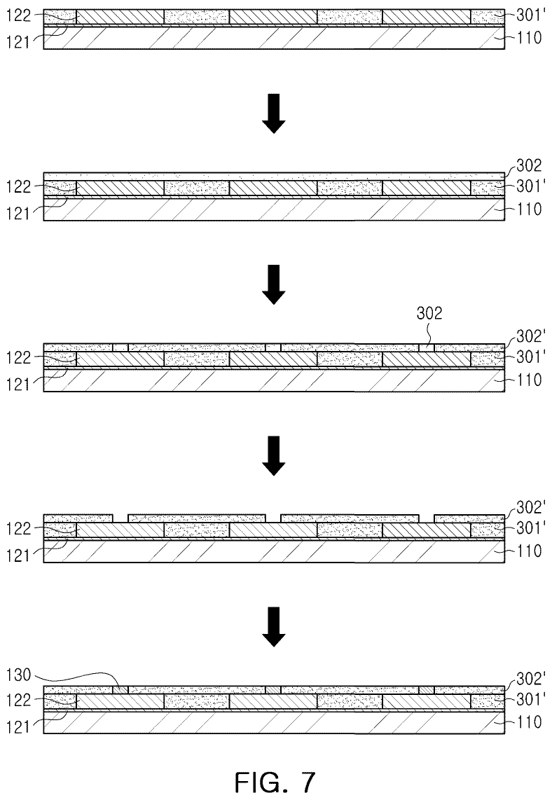

Referring to FIG. 7, a second metal layer 122 may be formed in a region from which at least a portion of the first dry film 301 is removed. An operation of forming the second metal layer 122 may be performed by electroplating. In this case, the operation of forming the second metal layer 122 may be performed by electroplating using the first metal layer 121 as a seed. In the operation of forming the second metal layer 122, a first dry film 301′ may function as a plating resist.

Thereafter, a second dry film 302 may be formed on the first dry film 301′. The second dry film 302 may have the same characteristics as the first dry film 301, but the present disclosure is not limited thereto, and the second dry film 302 may include a different type of photosensitive insulating material from the first dry film 301. In FIG. 7, the second dry film 302 is illustrated as being disposed on the first dry film 301, but it is not limited thereto, and an operation of removing the first dry film 301 may be included, before forming the second dry film 302. In this case, the second dry film 302 may be formed on the first insulating layer 110, after the first dry film 301 is removed.

Thereafter, a portion of the second dry film 302 may be exposed. In this case, a portion of the second dry film 302 may be exposed, considering a position on which a protrusion is later formed.

Thereafter, a portion of the second dry film 302 may be developed to remove at least a portion of the second dry film 302.

Thereafter, a protrusion 130 may be formed in a region from which the second dry film 302 is removed. An operation of forming the protrusion 130 may be performed by electroplating, but the present disclosure is not limited thereto. When the protrusion 130 is formed by electroplating, the electroplating may be performed on the second metal layer 122 using the first metal layer 121 as a seed. In this case, a second dry film 302′ modified by exposure and development may function as a plating resist. Since the protrusions 130 is additionally formed immediately after forming the second metal layer 122 on the first metal layer 121, the first metal layer 121 may be used as a seed for electroplating. However, it is not limited thereto, and the protrusion 130 may also be formed by attaching a metal material. When the protrusion 130 does not include a metal material, the protrusion 130 may be formed in an exposed region of the second dry film 302′ by various other methods, such as printing, liquid application, curing, etc. Alternatively, the second dry film 302 may include a positive type photosensitive insulating material, and the second dry film 302 may be patterned to correspond to the protrusion 130.

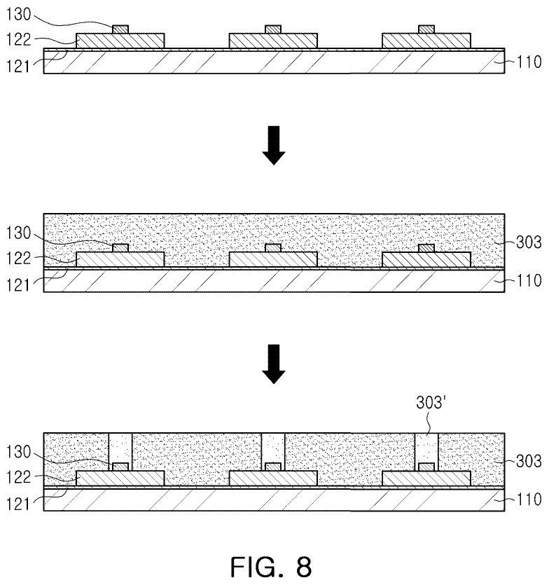

Referring to FIG. 8, the first dry film 301′ and the second dry film 302′ may be removed. As a method of removing the dry films, a method available to those skilled in the art may be used.

Thereafter, a third dry film 303 may be formed on the first insulating layer 110. The third dry film 303 may include a photosensitive insulating material, and a known dry film resist may be used. Since the description of the first dry film 301 may also be applied to the third dry film 303, overlapping descriptions will be omitted. The fact that the third dry film 303 is formed on the first insulating layer 110 may mean that the third dry film 303 is disposed on the first metal layer 121 formed on the first insulating layer 110, and may be formed to cover the second metal layer 122 and the protrusion 130. For example, a thickness of the third dry film 303 may be greater than a thickness from a lower surface of the second metal layer 122 to an upper surface of the protrusion 130. The third dry film 303 may be used to form a metal post, and a thickness thereof may be adjusted considering a height of the metal post.

Thereafter, a portion of the third dry film 303 may be exposed. In this case, exposure may be performed considering a region in which the metal post 140 will be formed, and in this case, a portion of the third dry film 303 may be modified. A region of a third dry film 303′ that has been exposed and modified may correspond to the protrusion 130. The fact that the region of the third dry film 303′ corresponds to the protrusion 130 may mean that a central portion of an exposed region of the third dry film 303′ is located in a central portion of the protrusion 130, and may also mean that a width of the exposed region of the third dry film 303′ is formed to be greater than a width of the protrusion 130.

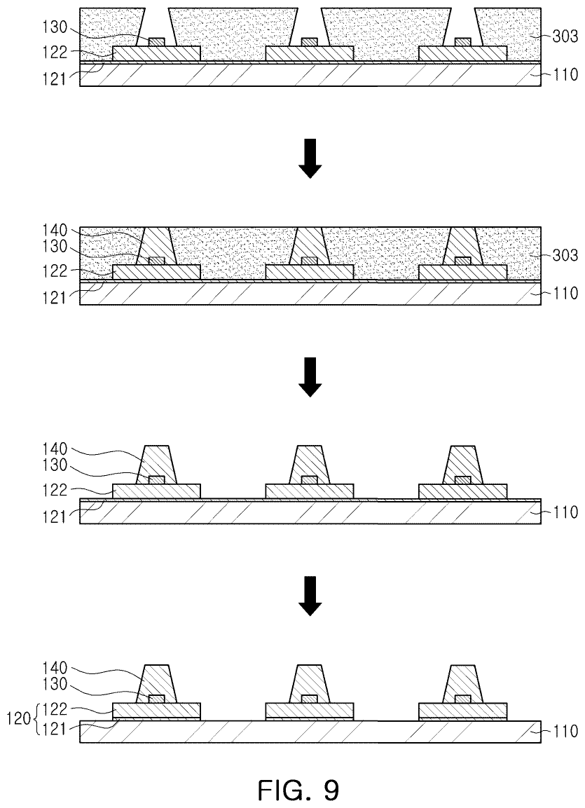

Referring to FIG. 9, the third dry film 303 may be developed to remove a region of the third dry film 303′ to form an opening. The opening formed in the third dry film 303 may correspond to a region for forming the metal post 140. In this case, an operation of developing the third dry film 303 may be performed by injecting a liquid type developer. Since the protrusion 130 is disposed in a lower portion of a region of the third dry film 303′ that has been modified by exposure, the developer may be injected along the protrusion 130 by injection pressure generated when injecting the developer. In the operation of developing the third dry film 303, a region of the third dry film 303 that are not exposed may also be removed. Therefore, the opening formed in the third dry film 303 may have an upwardly tapered shape. Since the third dry film 303 may be developed by injecting the developer, an opening having an upwardly tapered shape may be formed without forming a plurality of layers, and an opening having an upwardly tapered shape may be formed without a process of turning the same upside down.

Afterwards, a metal post 140 is formed on the second metal layer 122. The metal post 140 may be formed to fill the opening formed in the third dry film 303, and the formation may be performed by electroplating, but the present disclosure is not limited thereto. When the metal post 140 is formed by electroplating, the electroplating may be performed on the second metal layer 122 using the first metal layer 121, as a seed. In this case, the metal post 140 may be formed to cover the protrusion 130, and the third dry film 303 may function as a plating resist.

Afterwards, the third dry film 303 may be removed. To remove the dry film, a method available to those skilled in the art may be used.

Thereafter, at least portion of the first metal layer 121 may be removed. To remove portion of the first metal layer 121, known methods for removing the seed layer, such as etching, etc. may be used. Any method available to those skilled in the art may be used. By removing at least a portion of the first metal layer 121, the pad 120 composed of the first metal layer 121 and the second metal layer 122 may be completed, and may be used as a signal path together with the metal post 140.

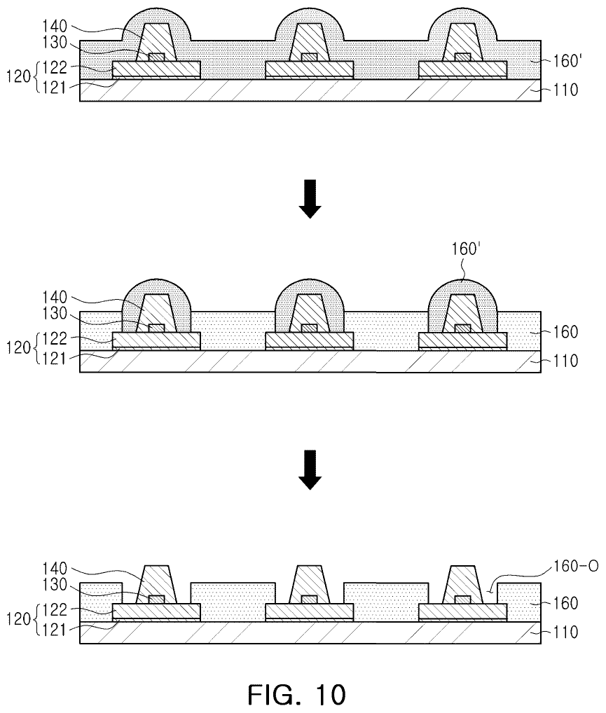

Referring to FIG. 10, a solder resist layer 160 may be formed on the first insulating layer 110. The solder resist layer 160 may be formed by applying an insulating material of a solder resist layer 160′, curing a portion thereof, and removing a remaining portion.

Since the metal post 140 of a printed circuit board according to an example has a protruding structure, a liquid material for the solder resist layer 160 may be used. When the liquid material is used as the solder resist layer 160, unlike a film-type solder resist, a heat press process is not involved. Therefore, the metal post 140 may be safe from deformation.

After applying the solder resist layer 160′ in a liquid state, exposure and development may be performed on regions corresponding to the pad 120 and the metal post 140 to form an opening 160-O. At least a portion of the pad 120 and the metal post 140 may be exposed through the opening 160-O of the solder resist layer 160.

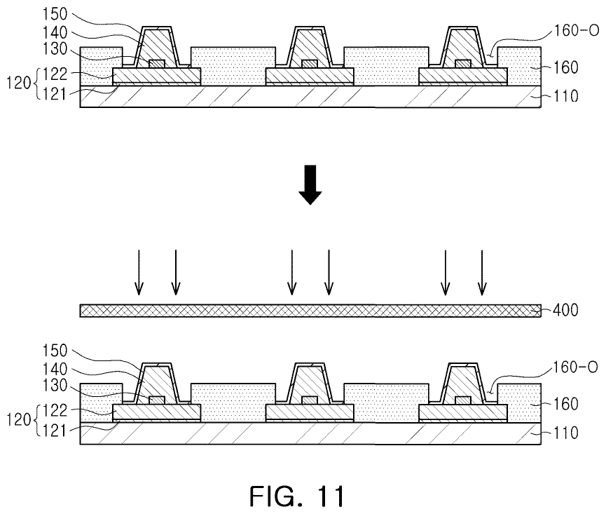

Referring to FIG. 11, a surface treatment layer 150 may be formed on at least a portion of the pad 120 and the metal post 140, exposed through the opening 160-O. A method of forming the surface treatment layer 150 may be differ depending on a material and a structure of the surface treatment layer 150, but any method available to those skilled in the art may be used.

Afterwards, a height of the metal post 140 may be uniformly adjusted using an apparatus 400. For example, an upper surface of the metal post 140 may be planarized using the apparatus 400. The apparatus 400 may be an apparatus for processing a substrate for coining, and the height of the metal post 140 may be uniformly adjusted using a pressurizing device attached to the apparatus 400. The height of the metal post 140 may be adjusted such that heights of the plurality of metal posts 140 are substantially the same, a defect rate may be reduced in a subsequent operation of forming a connection member, which may be advantageous when mounting a semiconductor chip. Additionally, in this process, since an area of the upper surface of the metal post 140 may also be adjusted, the metal post 140 may be adjusted to fit a size design of a connection member 170.

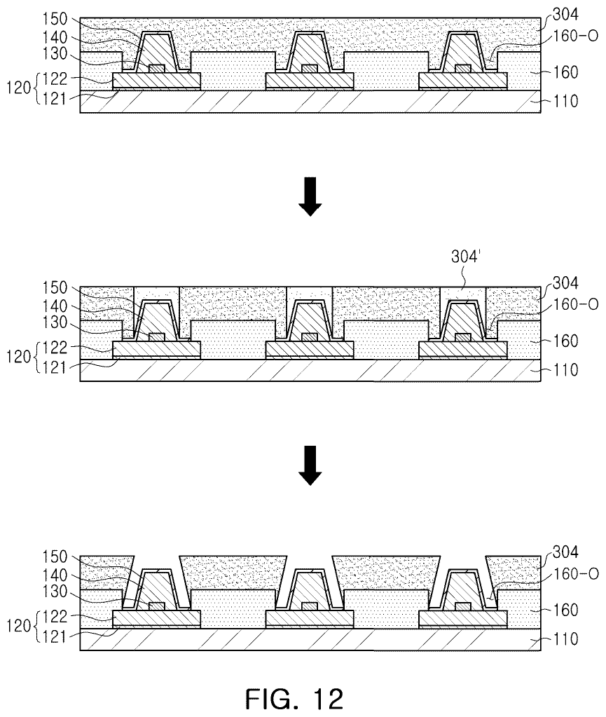

Referring to FIG. 12, a fourth dry film 304 may be formed on the solder resist layer 160. The fourth dry film 304 may be used as a means aligning metal posts 140, in an operation of forming the connection member 170. The fourth dry film 304 may include a photosensitive insulating material, and a known dry film resist may be used. Since the description of the first dry film 301 and the description of the third dry film 303 may also be applied to the fourth dry film 304, overlapping descriptions will be omitted. Since the fourth dry film 304 is disposed on the solder resist layer 160 containing a photosensitive insulating material, the fourth dry film 304 may use a material that is more sensitive to peeling, as compared to the solder resist layer 160. In this case, a thickness of the fourth dry film 304 may be greater than a thickness of the metal post 140. The fourth dry film 304 should be disposed to cover the metal post 140, and the fact that the thickness of the fourth dry film 304 is greater than the thickness of the metal post 140 may mean that an upper surface of the fourth dry film 304 is located higher than an upper surface of the metal post 140.

Thereafter, exposure may be performed on some regions of the fourth dry film 304. Since the fourth dry film 304 includes a photosensitive insulating material, a fourth dry film 304′ in the exposed region may be modified.

Thereafter, the fourth dry film 304 may be developed to remove a region of the fourth dry film 304′ to form an opening. An operation of developing the fourth dry film 304 may also use a method of injecting a liquid type developer. In this case, since the developer may be injected along an outer surface of the metal post 140, the opening formed in the fourth dry film may also have a shape tapered in an upward direction. The present disclosure is not necessarily limited thereto, and the opening formed in the fourth dry film may be formed such that upper and lower widths are substantially the same. Since the forming the opening by developing the fourth dry film 304′ corresponds to alignment for forming the connection member, it may be sufficient if a width of an upper surface of the opening is wider than a width of an upper surface of the metal post 140. In this case, the width of the upper surface of the opening may be determined by considering a design of the connection member 170, the width of the upper surface of the metal post 140, and the width and size of the connection member 170 should be considered, and it may be designed by comprehensively considering process capabilities, processing resolution, or the like.

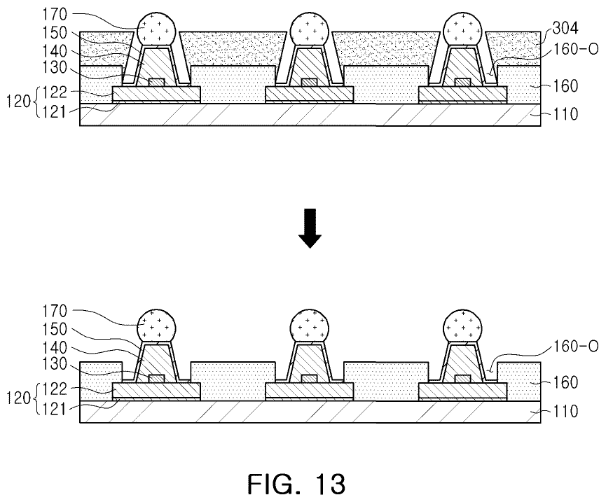

Referring to FIG. 13, a connection member 170 may be formed on the metal post 140 through the opening formed in the fourth dry film 304. Forming the connection member 170 on the metal post 140 may have the same meaning as forming the connection member 170 on the surface treatment layer 150 disposed on the metal post 140. An operation of forming the connection member 170 may include forming a viscous flux on the surface treatment layer 150, disposing the connection member 170, and then reflowing. The present disclosure is not necessarily limited to the above-described process, and any process that allows the connection member 170 to be arranged in a ball shape on the metal post 140 may be used without limitation.

Thereafter, the fourth dry film 304 may be removed. Since the solder resist layer 160 and the fourth dry film 304 may each include a photosensitive insulating material, there may be a problem that a portion of the solder resist layer 160 may be removed when the fourth dry film 304 may be removed. To prevent this, as described above, the fourth dry film 304 may be designed to include a material that may be more sensitive to peeling than the solder resist layer 160. For example, since the fourth dry film 304 may be peeled off more easily than the solder resist layer 160, it will be possible to remove only the fourth dry film 304.

As described above, a method of manufacturing a printed circuit board according to an example is not limited to those illustrated in FIGS. 6 to 13. As described above in a configuration of a printed circuit board according to an example, other components may be further included on a lower surface of the first insulating layer 110.

A printed circuit board according to another example may further include mounting a semiconductor chip 200 on the connection member 170 of a printed circuit board according to the example.

In the present disclosure, the meaning of “cross-section” may mean the cross-sectional shape when the object is cut vertically, or the cross-sectional shape when the object is viewed from a side surface direction. In addition, the meaning of “on a plane” may mean a plane shape when the object is cut horizontally, or a plane shape when the object is viewed from a top-view or bottom-view.

In the present disclosure, lower side, lower portion, bottom, lower surface, and the like are used for convenience to mean a downward direction based on the cross-section of the drawing. Upper side, upper portion, upper surface, top, and the like are used to mean the opposite direction. However, this direction is defined for convenience of explanation, and of course, the scope of the patent claims is not particularly limited by the description of this direction. The concept of top/bottom may change at any time.

In the present disclosure, the meaning of connected is a concept that includes not only directly connected, but also indirectly connected through an adhesive layer or the like. In addition, the meaning of being electrically connected is a concept that includes both cases where it is physically connected and cases where it is not connected. Additionally, expressions such as first, second, and the like are used to distinguish one component from another component and do not limit the order and/or importance of the components, and the like. In some cases, the first component may be named the second component, and similarly, the second component may be named as the first component, without departing from the scope of rights.

In the present disclosure, the judgment may actually include process errors, positional deviations, errors during measurement, etc., that occur during the manufacturing process. For example, substantially vertical may include not only completely vertical, but also approximately vertical. In addition, substantially coplanar may include not only the case of being completely on the same plane, but also the case of being approximately on the same plane.

In the present disclosure, the same material may mean not only the exact same material but also including the same type of material. Accordingly, the composition of the materials may be substantially the same, but their specific composition ratios may be slightly different.

The expression ‘example’ used in the present disclosure does not mean identical embodiments, but is provided to emphasize and explain different unique features. However, the examples presented above do not exclude being implemented in combination with features of other examples. For example, even if what is described in an example is not described in another example, unless there is a contrary or contradictory explanation in another example, it may be understood as an explanation related to another example.

The terminology used in this disclosure is used to describe examples only and is not intended to limit the disclosure. In this case, singular expressions include plural expressions, unless the context clearly indicates otherwise.

As one of the many effects of the present disclosure, a printed circuit board implementing a metal post with a fine pitch in the printed circuit board for mounting an electronic component, a semiconductor chip, or the like, and a method of manufacturing the printed circuit board, may be provided.

As an effect among the various effects of the present disclosure, a printed circuit board implementing a protruding metal post without etching an insulating layer, and a method of manufacturing the printed circuit board, may be provided.

As an effect among the various effects of the present disclosure, a printed circuit board improving reliability, and a method of manufacturing the printed circuit board, may be provided.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a first insulating layer;
a pad disposed on an upper side of the first insulating layer;
a protrusion disposed on the pad; and
a metal post disposed on the pad and covering the protrusion,
wherein the metal post has a tapered shape, such that a width of an upper surface of the metal post is smaller than a width of a lower surface of the metal post.

2. The printed circuit board of claim 1, wherein a width of the metal post is smaller than a width of the pad.

3. The printed circuit board of claim 1, further comprising a solder resist layer disposed on the first insulating layer.

4. The printed circuit board of claim 3, wherein the solder resist layer has an opening exposing at least a portion of the pad and at least a portion of the metal post.

5. The printed circuit board of claim 1, further comprising a surface treatment layer covering at least a portion of an upper surface of the pad and at least a portion of the metal post.

6. The printed circuit board of claim 1, wherein the pad comprises a first metal layer disposed on the first insulating layer, and a second metal layer disposed on the first metal layer.

7. The printed circuit board of claim 1, wherein the protrusion includes a metal material.

8. The printed circuit board of claim 1, further comprising a connection member disposed on the metal post.

9. The printed circuit board of claim 8, further comprising a semiconductor chip disposed on the metal post and including a body and a connection pad, and
the connection member connects the metal post and the semiconductor chip to each other.

10. The printed circuit board of claim 9, wherein a width of a surface of the connection member facing the connection pad is greater than a width of a surface of the connection member facing the metal post.

11. A method of manufacturing a printed circuit board, comprising:
forming a pad on a first insulating layer;
forming a protrusion on the pad; and
forming a metal post on the pad to cover the protrusion,
wherein the metal post has a tapered shape, such that a width of an upper surface of the metal post is smaller than a width of a lower surface of the metal post.

12. The method of claim 11, wherein the forming a metal post comprises forming a dry film on the first insulating layer, exposing and developing at least a portion of the dry film to expose at least a portion of the pad and at least a portion of the protrusion, and forming the metal post on the pad.

13. The method of claim 12, wherein the developing at least a portion of the dry film comprises injecting a developer containing a liquid material, to form an opening having a tapered shape, such that a width of an upper surface of the opening is smaller than a width of a lower surface of the opening.

14. The method of claim 11, wherein the forming a pad comprises forming a first metal layer on the first insulating layer by electroless plating, and forming a second metal layer on the first metal layer by electroplating,
the forming a protrusion comprises forming the protrusion on the second metal layer by electroplating, and
the forming a metal post comprises forming the metal post on the second metal layer by electroplating.

15. The method of claim 11, further comprising, after the forming a metal post, forming a connection member on the metal post.

16. The method of claim 15, further comprising, before the forming a connection member, planarizing the metal post.

17. A printed circuit board comprising:
a first insulating layer;
a pad disposed on an upper side of the first insulating layer;
a protrusion disposed on and protruding upwardly from an upper surface of the pad, the protrusion having a width smaller than a width of the pad; and
a metal post disposed on the pad and covering an upper surface and a side surface of the protrusion.

18. The printed circuit board of claim 1, wherein the metal post has a tapered shape, such that a width of an upper surface of the metal post is smaller than a width of a lower surface of the metal post

19. The printed circuit board of claim 1, wherein a width of the metal post is smaller than a width of the pad.
